(19) United States
(12) Patent Application Publication
(10) Pub. No.: US 2026/0212059 A1
(43) Pub. Date: Jul. 23, 2026

(54) INFORMATION PROCESSING APPARATUS, INFORMATION PROCESSING METHOD, AND NON-TRANSITORY COMPUTER-READABLE MEDIUM

(71) Applicant: NEC Corporation, Tokyo (JP)

(72) Inventors: Yasuhiko YOSHIDA, Tokyo (JP); Rui KONDO, Tokyo (JP); Ryohei WADA, Tokyo (JP)

(73) Assignee: NEC Corporation, Tokyo (JP)

(21) Appl. No.: 19/440,791

(22) Filed: Jan. 6, 2026

(30) Foreign Application Priority Data
Jan. 20, 2025 (JP) 2025-007870

(51) Int. Cl. G06F 30/13

(52) U.S. Cl. CPC G06F 30/13

(57) ABSTRACT

An information processing device of the present disclosure includes an acceptance unit, a generation unit, a determination unit, and an output unit. The acceptance unit accepts designation of a target date and time and a target place. The generation unit generates a virtual space in which the real world is reproduced, the virtual space being a simulation virtual space in which a situation of the target place on the target date and time is achieved. The determination unit determines candidates for an action to be performed at the target place on the target date and time based on the situation of the target place on the target date and time. The output unit outputs the simulation virtual space and information indicating the candidates for an action.

This application is based upon and claims the benefit of priority from Japanese patent application No. 2025-7870, filed on Jan. 20, 2025, the disclosure of which is incorporated herein in its entirety by reference.

### TECHNICAL FIELD

The present disclosure relates to an information processing device, an information processing method, and a non-transitory computer-readable medium.

### BACKGROUND ART

A technology related to this disclosure is disclosed in JP 2024-273 A. The technology disclosed in JP 2024-273 A collects information in the real world and reproduces a service state in the real world in a virtual space in real time. Then, the technology executes service simulation in the virtual space and predicts a future service state.

### SUMMARY

Various services using a virtual space in which the real world is reproduced have been studied. An example of the object of this disclosure is to develop a service using a virtual space in which the real world is reproduced.

According to one aspect of the present disclosure, there is provided an information processing device including,
an acceptance means for accepting designation of a target date and time and a target place,
a generation means for generating a virtual space in which a real world is reproduced, the virtual space being a simulation virtual space in which a situation of the target place on the target date and time is achieved,
a determination means for determining, based on a situation of the target place on the target date and time, candidates for an action to be performed at the target place on the target date and time, and
an output means for outputting the simulation virtual space and information indicating the candidates for an action.

Furthermore, according to one aspect of the present disclosure, there is provided an information processing method, in which one or more computers,
accept designation of a target date and time and a target place,
generate a virtual space in which a real world is reproduced, the virtual space being a simulation virtual space in which a situation of the target place on the target date and time is achieved,
determine, based on a situation of the target place on the target date and time, candidates for an action to be performed at the target place on the target date and time, and
output the simulation virtual space and information indicating the candidates for an action.

Moreover, according to one aspect of the present disclosure, there is provided a program for causing a computer to execute processing including,
accepting designation of a target date and time and a target place,
generating a virtual space in which a real world is reproduced, the virtual space being a simulation virtual space in which a situation of the target place on the target date and time is achieved,
determining, based on a situation of the target place on the target date and time, candidates for an action to be performed at the target place on the target date and time, and
outputting the simulation virtual space and information indicating the candidates for an action.

According to an example of this disclosure, a service using a virtual space in which the real world is reproduced can be developed.

### BRIEF DESCRIPTION OF THE DRAWINGS

FIG. 1 is a diagram illustrating an example of a functional block diagram of an information processing device;

FIG. 2 is a flowchart illustrating an example of a flow of processing of the information processing device;

FIG. 3 is a diagram illustrating an example of a hardware configuration of the information processing device;

FIG. 4 is a diagram schematically illustrating an example of information processed by the information processing device;

FIG. 5 is a diagram illustrating an example of a screen output by the information processing device; and

FIG. 6 is a diagram illustrating an example of information generated by the information processing device.

### EXAMPLE EMBODIMENT

Hereinafter, an example embodiment of the present disclosure will be described with reference to the drawings. In this disclosure, the drawings are associated with one or more example embodiments. In all the drawings, the same components are denoted by the same reference signs, and description thereof will be omitted as appropriate.

### First Example Embodiment

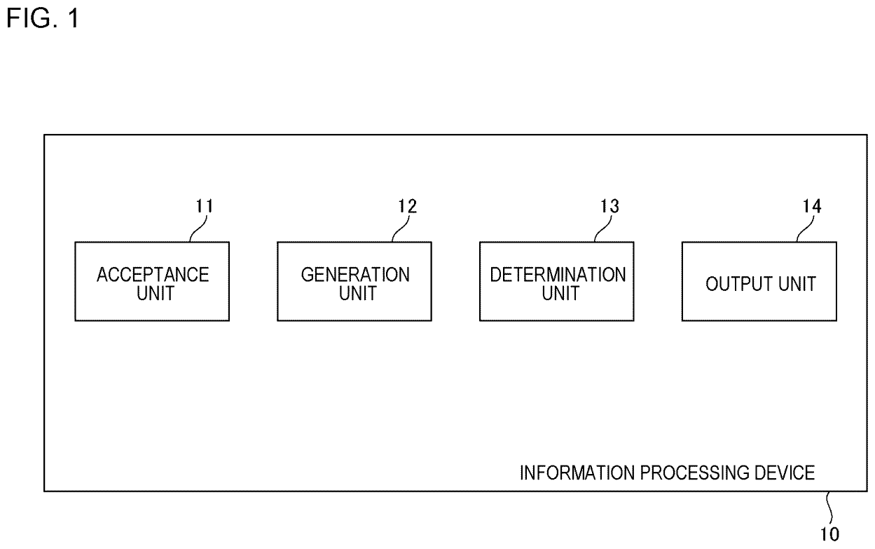

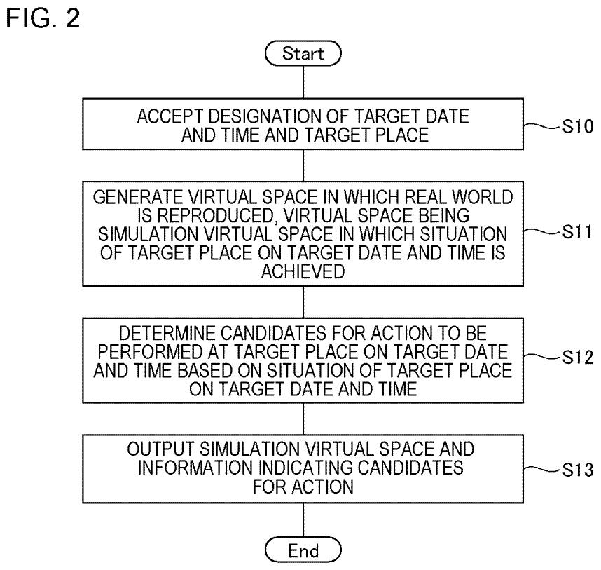

FIG. 1 is a functional block diagram illustrating an outline of an information processing device 10. FIG. 2 is a flowchart illustrating an example of a flow of processing executed by the information processing device 10.

As illustrated in FIG. 1, the information processing device 10 includes an acceptance unit 11, a generation unit 12, a determination unit 13, and an output unit 14. The processing shown in the flowchart of FIG. 2 is executed by these functional units.

In S10, the acceptance unit 11 accepts designation of a target date and time and a target place.

In S11, the generation unit 12 generates a virtual space in which the real world is reproduced, the virtual space being a simulation virtual space in which the situation of the target place on the target date and time is achieved (expressed).

In S12, the determination unit 13 determines candidates for an action to be performed at the target place on the target date and time based on the situation of the target place on the target date and time.

In S13, the output unit 14 outputs information indicating the simulation virtual space and the candidates for the action determined in S12.

The processing order of S11 and S12 is not limited to this example. For example, S12 may be performed before S11, or S11 and S12 may be performed in parallel.

Meanwhile, there is a case where a current or future action plan is considered. For example, there is a case of considering what to do at a travel destination before the travel. Furthermore, there is a case of considering a date plan before the date. In addition, there is a case of considering what to do from now while traveling or on a date.

In considering the action plan, it is important to grasp what kind of facility is present at the visit place. If what kind of facility is present at the visit place can be grasped, it becomes possible to more efficiently create an action plan with a higher degree of satisfaction.

As an example of a means for grasping what kind of facility is present at the visit place, use of a service for connecting panoramic images photographed at various points and providing an image of a target position designated by the user is conceivable. The service presents an image at a target position designated by the user. Then, the service accepts a user operation for moving the target position, and newly presents an image at the moved target position. By using the service, the user can confirm an image at each target position while shifting the target position little by little, and can grasp facilities around the target position.

However, the situation of the visit place is not always the same, and may change depending on the date and time. For example, a business day and a business hours are determined in each facility. For this reason, each facility has a timing of being opened and a timing of being closed. In addition, the weather at the visit place may be different for each timing.

In the case of the service using the panoramic image, the user can merely grasp the situation at the timing the image was photographed by confirming the presented image, and cannot grasp the situation of the place at the visit date and time. If the situation of the visit place at the visit date and time can be grasped, it becomes possible to more efficiently create an action plan with a higher degree of satisfaction. The information processing device 10 is configured to be able to solve such a problem.

As described above, the information processing device 10 can generate and output the “simulation virtual space in which the situation of the target place on the target date and time is achieved”. The user can grasp the situation of the target place on the target date and time by confirming the output simulation virtual space. Then, the user can determine an action to be performed at the target place on the target date and time in consideration of the situation of the target place on the target date and time. As a result, the user can more efficiently create an action plan with a higher degree of satisfaction.

Furthermore, the information processing device 10 can determine and output “candidates for an action to be performed at the target place on the target date and time”. The user can determine what to do at the target place on the target date and time from among the candidates determined by the information processing device 10. For example, the user can determine what to do at the target place on the target date and time from among the candidates for the actions determined by the information processing device 10 in consideration of the situation of the target place on the target date and time indicated in the simulation virtual space. As a result, the user can more efficiently create an action plan with a higher degree of satisfaction.

Furthermore, the information processing device 10 can determine candidates for an action to be performed at the target place on the target date and time “based on the situation of the target place on the target date and time”. Therefore, the candidates for the action determined by the information processing device 10 has contents reflecting the situation of the target place on the target date and time. By providing such a candidate to the user, the user can more efficiently create an action plan with a higher degree of satisfaction.

According to such an information processing device 10, a service using a virtual space in which the real world is reproduced can be developed.

### Second Example Embodiment

### Outline

An information processing device 10 of a second example embodiment is obtained by embodying the configuration of the information processing device 10 of the first example embodiment. Details will be described below.

### Hardware Configuration

First, an example of a hardware configuration of the information processing device 10 will be described. Each functional unit of the information processing device 10 is achieved by any combination of hardware and software. It is to be understood by those skilled in the art that there are various modified examples of the implementation method and the device. The software includes a program stored in advance from a stage of shipping the device, a program downloaded from a recording medium such as a Compact Disc (CD), a server on the Internet, or the like.

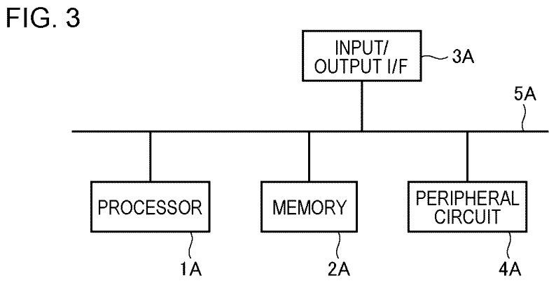

FIG. 3 is a block diagram illustrating a hardware configuration of the information processing device 10. As illustrated in FIG. 3, the information processing device 10 includes a processor 1A, a memory 2A, an input/output interface 3A, a peripheral circuit 4A, and a bus 5A. The peripheral circuit 4A includes various modules. The information processing device 10 does not necessarily include the peripheral circuit 4A. The information processing device 10 may include a plurality of physically and/or logically separated devices. In this case, each of the plurality of devices can have the above-described hardware configuration.

The bus 5A is a data transmission path through which the processor 1A, the memory 2A, the peripheral circuit 4A, and the input/output interface 3A mutually transmit and receive data. The processor 1A is, for example, an arithmetic processing device such as a Central Processing Unit (CPU) or a Graphics Processing Unit (GPU). The memory 2A is, for example, a memory such as a Random Access Memory (RAM) or a Read Only Memory (ROM). The input/output interface 3A includes an interface for acquiring information from an input device, an external device, an external server, an external sensor, a camera, and the like, and an interface for outputting information to an output device, an external device, an external server, and the like. In addition, the input/output interface 3A includes an interface for connecting to a communication network such as the Internet. The input device is, for example, a keyboard, a mouse, a microphone, a physical button, a touch panel, or the like. The output device is, for example, a display, a projection device, a speaker, a printer, a mailer, or the like. The processor 1A can issue commands to the modules and execute calculation based on calculation results by the modules.

### Functional Configuration

Next, a functional configuration of the information processing device 10 will be described in detail. FIG. 1 is an example of a functional block diagram of the information processing device 10. As illustrated in the figure, the information processing device 10 includes an acceptance unit 11, a generation unit 12, a determination unit 13, and an output unit 14.

The acceptance unit 11 accepts designation of a target date and time and a target place.

The “target date and time” is a date and time of visiting the target place. The current or future specific date and time is the target date and time. The acceptance unit 11 may be able to accept a past specific date and time as the target date and time.

The acceptance unit 11 may be able to accept a date and time designated by the user as the target date and time. For example, the user can designate a future date and time as the target date and time. As a usage scene of this example, an example is conceivable in which a user considering an action plan at a target place to visit in the future designates a future date and time (visiting date and time) of visiting the target place as the target date and time.

In addition, the user can designate the current date and time as the target date and time. As a usage scene of this example, an example is conceivable in which a user who is visiting a target place and is considering a future action plan designates a current date and time (visiting date and time) as the target date and time.

The acceptance unit 11 can accept designation of the target date and time via the UI screen that accepts input of the target date and time.

The acceptance unit 11 can accept user input via various input devices such as a touch panel, a keyboard, a mouse, a physical button, and a microphone. In addition, the information processing device 10 may be a server. Then, the acceptance unit 11 may operate the user terminal to acquire information indicating the target date and time designated by the user from the user terminal. Examples of the user terminal include, but are not limited to, for example, a smartphone, a personal computer, a tablet terminal, a mobile phone, a headset, and other wearable terminals.

In another example, the acceptance unit 11 can accept the current date and time as the target date and time without user input. The acceptance unit 11 can acquire information indicating the current date and time (target date and time) from a clock function included in the information processing device 10, a server that notifies the current date and time, or the like.

The “user” is a person who uses a service provided by the information processing device 10. The user can create an action plan at the target place on the target date and time using the information processing device 10.

The “target place” is a place to be visited on the target date and time.

In one example, the acceptance unit 11 can accept a place designated by the user as the target place. For example, the user can designate a place (visiting place) scheduled to visit on the target date and time as the target place. In addition, the user can designate the current position as the target place. Then, the acceptance unit 11 can accept a place designated by the user as a target place. The acceptance unit 11 can accept designation of the target place via the UI screen that accepts input of the target place.

The acceptance unit 11 can accept user input via various input devices such as a touch panel, a keyboard, a mouse, a physical button, and a microphone. In addition, the information processing device 10 may be a server. Then, the acceptance unit 11 may operate the user terminal to acquire information indicating the target place designated by the user from the user terminal. Examples of the user terminal include, but are not limited to, for example, a smartphone, a personal computer, a tablet terminal, a mobile phone, a headset, and other wearable terminals.

A map may be displayed on the UI screen. Then, the user may perform an input to designate the target place on the map. In this case, for example, the acceptance unit 11 can acquire the latitude and longitude information of the position designated on the map as the information indicating the target place.

In addition, on the UI screen, a UI component that accepts input of an address or a name of a spot (e.g., Tokyo Station) may be displayed. Then, the user may perform acceptance of an input of the target place via the UI component. In this case, for example, the acceptance unit 11 can acquire the latitude and longitude information of the input address or the representative point at the spot as the information indicating the target place. Each address and a representative point of each spot may be registered in advance. In addition, the acceptance unit 11 may determine each address and a representative point of each spot based on a predetermined rule. The predetermined rule is “a center point in an area of each address or each spot” or the like, but is not limited thereto.

In another example, the acceptance unit 11 can accept the current position of the user as the target place without user input. The acceptance unit 11 can acquire information indicating the current position of the user from the user terminal possessed by the user. The acceptance unit 11 may acquire current position information indicating the current position (target place) of the user terminal from the user terminal possessed by the user. The user terminal can have a position information acquisition function such as a global positioning system (GPS).

The generation unit 12 generates a virtual space in which the real world is reproduced, the virtual space being a simulation virtual space in which the situation of the target place on the target date and time is achieved.

The “virtual space” is a virtual space built on a computer or a network.

The “virtual space in which the real world is reproduced” is a space constituted by elements similar to those in the real world. That is, in a virtual space in which the real world is reproduced, elements existing in the real world exist in an arrangement relationship similar to that in the real world. Examples of the element include an artificial object (facility, building, road, traffic light, etc.) and a natural object (river, mountain, tree, etc.), but are not limited thereto. The virtual space in which the real world is reproduced can be achieved by, for example, a technology such as a digital twin.

The “simulation virtual space” is a virtual space in which the real world is reproduced. Then, in the simulation virtual space, the situation of the target place on the target date and time is achieved.

The generation unit 12 specifies the situation of the target place on the target date and time based on at least one of the following information. Then, the generation unit 12 generates a simulation virtual space in which the specified situation is achieved.
Date and time related information of each of a plurality of facilities existing in real world
Weather information of real world
Sunrise and sunset times of real world

### Date and Time Related Information of Each of a Plurality of Facilities Existing in the Real World

The date and time related information of each of the plurality of facilities existing in the real world is information related to each of the plurality of facilities existing in the real world and is information related to date and time. The date and time related information is information related to each of the facilities, and can include information defining contents by using date and time. In addition, the date and time related information is information related to each of the facilities, and can include information whose content can be different for each date and time.

The date and time related information may include, for example, at least one of a business hours, a crowding situation of a target place, and a date and time of an event held in a facility. The date and time related information may include, for example, at least one of the following:
Business Day
Business hours
Crowding tendency for each time zone in one day
Crowding tendency for each day of week
Crowding tendency for each month
Crowding situation at current time point
Reservation status of facility
Date and time of event held in facility

“Business day” is a day on which each facility is open. For example, a business day may be indicated by defining a closed day.

“Business hours” indicates a time zone in which each facility is open. For example, the business hours may be indicated by the business start time and the business end time.

“Crowding tendency for each time zone in one day ” indicates a crowding tendency of each facility in each time zone. For example, the business hours may be divided every predetermined time (example: every 30 minutes, every 1 hour), and a crowding tendency in each divided time zone may be indicated. The crowding tendency is indicated by any means such as 10 grade evaluation or 5 grade evaluation.

“Crowding tendency for each day of week” indicates a crowding tendency of each facility on each day of the week. The crowding tendency is indicated by any means such as 10 grade evaluation or 5 grade evaluation.

“Crowding tendency for each month” indicates a crowding tendency of each facility in each month. The crowding tendency is indicated by any means such as 10 grade evaluation or 5 grade evaluation.

“Crowding situation at current time point” indicates the crowding situation of the facility at the current time point. The crowding situation is indicated by any means such as 10 grade evaluation or 5 grade evaluation.

“Reservation status of facility” indicates the reservation status of the facility at the current time point. Among the facilities, there are facilities that can be reserved in advance. Examples of the facilities that can be reserved in advance include, but are not limited to, amusement facilities, co-working spaces, and conference rooms. The reservation status of the facility indicates the contents of the reservation made at the current time point in such a facility that can be reserved in advance.

“Date and time of event held in facility” indicates the date and time of the event scheduled to be held in each facility.

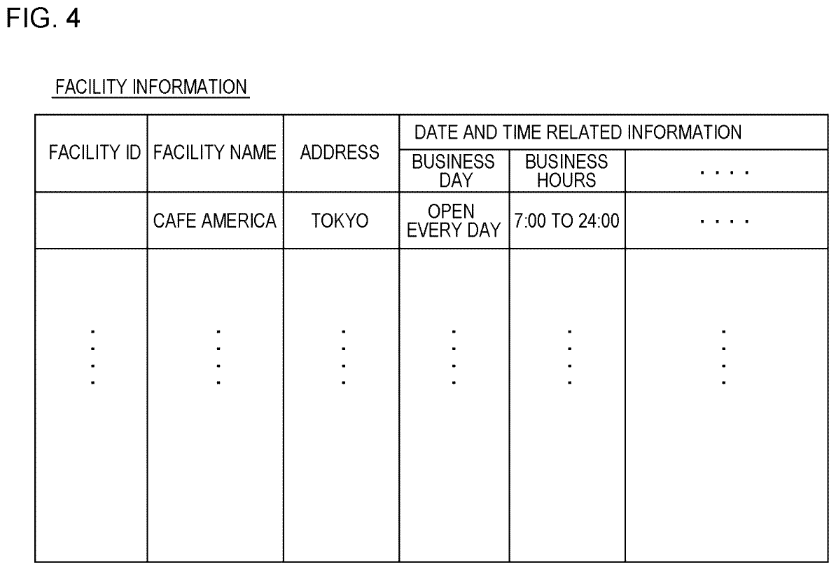

As illustrated in FIG. 4, facility information related to each of a plurality of facilities existing in the real world is stored in advance in a predetermined storage device. The predetermined storage device may be provided in the information processing device 10 or may be provided in an external device communicably connected to the information processing device 10. The generation unit 12 can specify the date and time related information of each facility with reference to such facility information.

In the facility information of FIG. 4, a facility identifier (ID) for identifying a plurality of facilities from each other, a facility name, an address, and date and time related information are associated with each other. The facility information may include other information such as the type of facility (cafes, karaoke, etc.) and the attribute of the facility (outdoor, indoor, underground, etc.).

The information processing device 10 can update facility information as illustrated in FIG. 4 at any time. The information processing device 10 can acquire information indicating updated contents from an external device. Then, the information processing device 10 can update the content of the facility information based on the acquired information. In addition, an operator may input information indicating the updated content to the information processing device 10.

The “acquisition” includes at least one of an own device obtaining data or information stored in another device or a storage medium (active acquisition) and an own device receiving an input of data or information output from another device (passive acquisition). Examples of the active acquisition include making a request or the like to another device and receiving a reply to the request, and accessing the another device or a storage medium for reading. Examples of the passive acquisition include receiving distributed (alternatively, transmitted, push-notified, etc.) information. Furthermore, “acquisition” may be selecting acquiring from received data or information, or selecting and receiving distributed data or information.

### Weather Information

The weather information is information related to weather in each region. The weather information may include at least one of weather, temperature, humidity, air volume, ultraviolet light amount, caution, and alarm. The weather information may include at least one of current weather information and future predicted weather information. The generation unit 12 can acquire weather information from, for example, a server providing weather information in each region.

### Sunrise and Sunset Times

The sunrise and sunset times are a sunrise time and a sunset time of each day in each region. The generation unit 12 can acquire the information from, for example, a server providing sunrise time and sunset time of each day in each region.

The generation unit 12 can specify the situation of the target place on the target date and time based on the information as described above, and generate the simulation virtual space in which the specific situation is achieved.

For example, the generation unit 12 specifies the temporal anteroposterior relationship between the target date and time and the sunrise and sunset by comparing the sunrise and sunset times of the target place on a day to which the target date and time belongs with the time of the target date and time. Then, in a case where the target date and time is before sunrise or after sunset, the generation unit 12 can express night by darkening the brightness of the simulation virtual space. In this case, the generation unit 12 may turn on a street lamp or the like existing in the simulation virtual space. Furthermore, in a case where the target date and time is after sunrise and before sunset, the generation unit 12 can express morning and noon by lightening the brightness of the simulation virtual space.

In addition, the generation unit 12 can express the weather environment of the target place on the target date and time in the simulation virtual space based on the weather information of the target place on the target date and time. For example, in the case of rain, the generation unit 12 can express the weather by displaying an image in which it is raining in the simulation virtual space. Furthermore, in the case of snow, the generation unit 12 can express the weather by displaying an image in which it is snowing in the simulation virtual space. Moreover, the generation unit 12 can express the strength of the wind by adjusting the amount of blowing an object (e.g., a flag etc.) existing in the simulation virtual space according to the strength of the wind. In addition, the generation unit 12 can express the temperature by changing the clothes of the character existing in the simulation virtual space according to the temperature. The generation unit 12 can make the character wear clothes suitable for the temperature.

In addition, the generation unit 12 can specify whether each facility is open on the target date and time by comparing the business day and the business hours of each facility with the target date and time. Then, the generation unit 12 can express whether each facility is open in the simulation virtual space.

For example, the generation unit 12 may perform display in which a facility that is open and a facility that is not open can be identified in the simulation virtual space. There are various display methods. For example, the generation unit 12 may display character information such as “open” in association with a facility that is open. In addition, the generation unit 12 may display a facility that is open relatively bright and display a facility that is not open relatively dark in the simulation virtual space.

In addition, the generation unit 12 can specify the crowding tendency and the crowding situation of each facility on the target date and time based on the information indicating the crowding tendency and the crowding situation at each timing of each facility. Then, the generation unit 12 can express a crowding tendency and a crowding situation of each facility on the target date and time in the simulation virtual space.

For example, the generation unit 12 may perform display in which a crowded facility and a non-crowded facility can be identified in the simulation virtual space. There are various display methods. For example, the generation unit 12 may display character information such as “crowded” in association with a crowded facility. In addition, the generation unit 12 may express that the facility is crowded by arranging a large number of characters in or in front of the crowded facility in the simulation virtual space.

In addition, the generation unit 12 can specify whether each facility can be used on the target date and time based on the reservation status of each facility. The generation unit 12 can specify whether there is an empty slot on the target date and time based on the reservation status of each facility. In a case where there is an empty slot, the generation unit 12 can determine that each facility can be used on the target date and time.

Then, the generation unit 12 can express whether each facility can be used on the target date and time in the simulation virtual space. For example, the generation unit 12 may perform display in which an available facility and an unavailable facility can be identified in the simulation virtual space. There are various display methods. For example, the generation unit 12 may display character information such as “available” in association with an available facility.

In addition, the generation unit 12 can specify whether an event is held on the target date and time based on information indicating the date and time of the event of each facility. Then, the generation unit 12 can express that an event is being held in each facility on the target date and time in the simulation virtual space.

For example, the generation unit 12 may perform display in which a facility holding an event and a facility not holding an event can be identified in the simulation virtual space. There are various display methods. For example, the generation unit 12 may display character information such as “holding an event” in association with a facility holding an event.

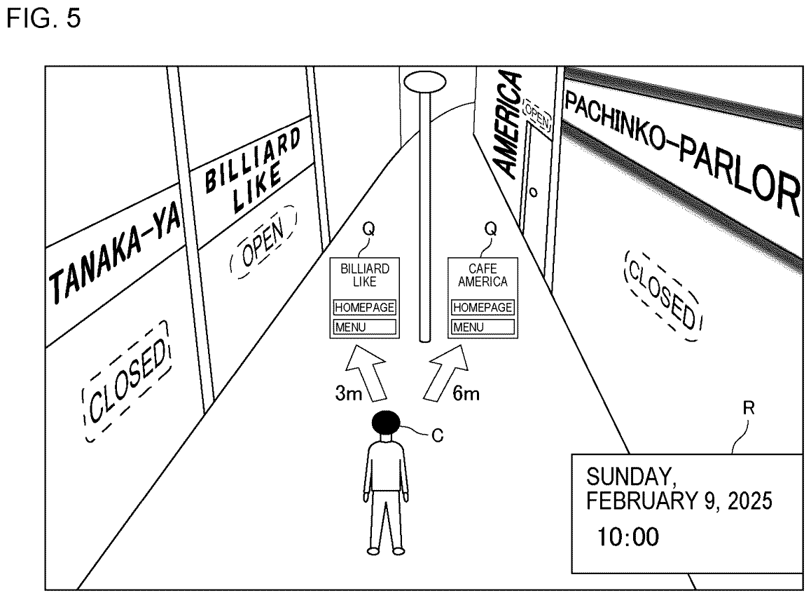

FIG. 5 schematically illustrates an example of the simulation virtual space generated by the generation unit 12. FIG. 5 is an example of a screen illustrating a state in which the simulation virtual space is viewed through the character C operated by the user. On the screen provided to the user, the simulation virtual space may be indicated from a third-person viewpoint as illustrated in FIG. 5, or the simulation virtual space may be indicated from a first-person viewpoint (the viewpoint of the character C operated by the user).

In the example of FIG. 5, the target date and time is shown at the lower right of the screen. Then, characters “open” or “closed” are displayed in association with each facility. These characters indicate the situation of each facility on the target date and time.

Returning to FIG. 1, the determination unit 13 determines candidates for an action to be performed at the target place on the target date and time based on the situation of the target place on the target date and time. For example, the determination unit 13 can determine candidates for an action to be performed at the target place on the target date and time with reference to the date and time related information of each facility. Furthermore, the determination unit 13 can determine candidates for an action to be performed at the target place on the target date and time based on the content of the weather information of the target place on the target date and time.

For example, the determination unit 13 can determine visit to any of the plurality of facilities as candidates for an action to be performed at the target place on the target date and time. Specifically, the determination unit 13 can narrow down the facilities to visit from among the plurality of facilities based on the situation of the target place on the target date and time. Then, the determination unit 13 can determine the narrowed facility as candidates for an action to be performed at the target place on the target date and time. Hereinafter, an example of the processing will be described, but this is not the sole case.

In one example, first, the determination unit 13 can narrow down facilities to visit based on the target place. For example, the determination unit 13 can narrow down facilities whose distance from the target place is within a threshold value. The threshold value is determined in advance.

Then, the determination unit 13 can further narrow down the facilities narrowed down in this manner based on the situation of the target place on the target date and time.

For example, the determination unit 13 can narrow down the facilities to a facility that satisfies a narrowing condition defined by at least one of the following or a narrowing condition defined by connecting a plurality of the following by a predetermined logical operator.
Open on target date and time
Crowding tendency on target date and time is equal to or less than a predetermined level (predetermined level is defined in advance)
Crowding situation on target date and time is equal to or less than a predetermined level (predetermined level is defined in advance.)
There is a vacant slot in the reservation status on the target date and time
Event is held on the target date and time
Combination of the facility attribute and the weather environment of the target place on the target date and time is not a non-recommended combination
Combination of the facility attribute and the weather environment of the target place on the target date and time is a recommended combination

The non-recommended combination is a combination of a certain weather environment and an attribute of a facility that is not preferable to be used at the time of such weather environment. Examples of the non-recommended combination include, but are not limited to, a combination of weather “rain” and a facility attribute “outdoor”, and a combination of temperature “equal to or lower than 5° C.” and a facility attribute “outdoor”.

The recommended combination is a combination of a certain weather environment and an attribute of a facility that is preferable to be used at the time of such weather environment. Examples of the recommended combination include, but are not limited to, a combination of weather “rain” and a facility attribute “underground”, and a combination of temperature “equal to or lower than 5° C.” and a facility attribute “indoor”.

The determination unit 13 can specify the facility attribute of each facility by referring to the facility information described above.

The output unit 14 outputs a screen displaying the simulation virtual space generated by the generation unit 12 and information indicating the candidates for the action determined by the determination unit 13. FIG. 5 schematically illustrates an example of the screen.

The screen shows a virtual space in which the real world is reproduced, the virtual space being a simulation virtual space in which the situation of the target place on the target date and time is achieved. Furthermore, the screen displays information indicating candidates for an action to be performed at the target place on the target date and time, determined based on the situation of the target place on the target date and time.

The information in Q of FIG. 5 is information indicating candidates for an action to be performed at the target place on the target date and time (hereinafter referred to as “guidance information”). The guidance information may indicate the name of a facility that is a candidate to visit. In addition, the guidance information may indicate various types of information of facilities that are candidates to visit. Various pieces of information of each facility may be stored in a predetermined storage device in advance. For example, the guidance information may indicate a link for accessing a home page of a facility that is a candidate to visit, a link for accessing a page introducing a menu of the facility, or the like. Furthermore, the guidance information may indicate a posted comment or a posted image (including still image and moving image) of each facility. In addition, the guidance information may indicate an advertisement of each facility. The advertisement may include moving image or voice. In addition, the guidance information may indicate a distance or a movement time from the target place to each facility. In addition, the guidance information may indicate a route from the target place to each facility with an arrow or the like. The indication of the distance to each facility and the magnitude of the movement time may be indicated by differing the display mode such as the color and size of the arrow. Furthermore, the guidance information may indicate any of the above-described date and time related information of each facility. The distance and the movement time from the target place to each facility can be calculated using a widely known route search technique.

Next, an example of a flow of processing of the information processing device 10 will be described with reference to the flowchart of FIG. 2. Here, an object is to describe an example of a flow of processing. Since the details of each processing have been described above, the description here will be appropriately omitted.

In S10, the information processing device 10 accepts designation of the target date and time and the target place.

In S11, the information processing device 10 generates a virtual space in which the real world is reproduced, the virtual space being a simulation virtual space in which the situation of the target place on the target date and time is achieved.

In S12, the information processing device 10 determines candidates for an action to be performed at the target place on the target date and time based on the situation of the target place on the target date and time.

In S13, the information processing device 10 outputs information indicating the simulation virtual space and the candidates for the action determined in S12.

In one example, the information processing device 10 can accept the target date and time and the target place designated by the user in S10. For example, the user can designate a place scheduled to visit in the future as a target place, and designate a visiting date and time as a target date and time.

In the case of this example, the information processing device 10 generates and outputs a simulation virtual space in which the situation of the target place on the future target date and time is achieved. Furthermore, the information processing device 10 determines and outputs candidates for an action to be performed at the target place on the future target date and time based on the situation of the target place on the future target date and time.

In another example, in S10, the information processing device 10 can accept the current date and time as the target date and time, and can accept the current position of the user as the target place.

In the case of this example, the information processing device 10 generates and outputs a simulation virtual space in which a situation of the current position (target place) of the user at the current time point (target date and time) is achieved. Furthermore, the information processing device 10 determines and outputs candidates for an action to be performed at the current position of the user at the current time point based on a situation of the current position (target place) of the user at the current time point (target date and time).

In the case of the example, the information processing device 10 may output a screen as illustrated in FIG. 5, or may present, to the user, candidates for an action to be performed at the current position of the user at the current time point by using augmented reality (AR) technology. In the case of this example, a live image photographed by the user terminal is displayed on the user terminal operated by the user. Then, the information processing device 10 displays information indicating candidates for an action to be performed at the current position of the user at the current time point, in superposition with the live image. Furthermore, the information processing device 10 may display information indicating the situation of the target place (the place), for example, information indicating the situation of each facility, in superposition with the live image. The display of the information indicating the situation of each facility can be achieved by a method similar to the display in the simulation virtual space. For example, the information processing device 10 can use device information such as a GPS and a gyro sensor mounted on the user terminal to update the display in real time in accordance with movement of the user and a change in viewpoint. As a result, the user can intuitively understand the current situation and the candidates for an action while viewing the real landscape, and can efficiently create the action plan. In a case where the AR technology is used, the information processing device 10 can issue a dynamic pricing leading advertisement in real time. The information processing device 10 may urge the advertiser side to issue an advertisement if human presence is predicted.

### Operations and Effects

According to the information processing device 10 of the second example embodiment, operations and effects similar to those of the information processing device 10 of the first example embodiment can be achieved.

Furthermore, the information processing device 10 can specify the situation of each facility on the target date and time, and generate and output the simulation virtual space expressing the specified content. The user can grasp the situation of each facility on the target date and time by confirming the output simulation virtual space. Then, the user can determine an action to be performed at the target place on the target date and time in consideration of the situation of each facility on the target date and time. As a result, the user can more efficiently create an action plan with a higher degree of satisfaction.

Furthermore, the information processing device 10 can specify the weather or the environment of the target place on the target date and time, and generate and output the simulation virtual space expressing the specified content. The user can grasp the weather and environment of the target place on the target date and time by confirming the output simulation virtual space. Then, the user can determine an action to be performed at the target place on the target date and time in consideration of the weather or environment of the target place on the target date and time. As a result, the user can more efficiently create an action plan with a higher degree of satisfaction.

Furthermore, the information processing device 10 can specify the situation of each facility on the target date and time, determine candidates for an action to be performed at the target place on the target date and time based on the specified content, and provide the candidates for the action to the user. Therefore, the candidates for the action determined by the information processing device 10 has contents reflecting the situation of each facility on the target date and time. For example, the information processing device 10 can determine a facility open on the target date and time as a candidate. Furthermore, the information processing device 10 can determine, as a candidate, a facility having a vacant slot in the reservation status on the target date and time. Furthermore, the information processing device 10 can determine a facility that is not very crowded on the target date and time as a candidate. By providing such a candidate to the user, the user can more efficiently create an action plan with a higher degree of satisfaction.

Furthermore, the information processing device 10 can specify the weather or environment of the target place on the target date and time, determine candidates for an action to be performed at the target place on the target date and time based on the specified content, and provide the candidates for the action to the user. Therefore, the candidates for the action determined by the information processing device 10 has contents reflecting the weather and environment of the target place on the target date and time. By providing such a candidate to the user, the user can more efficiently create an action plan with a higher degree of satisfaction.

Furthermore, the information processing device 10 can accept a place scheduled to visit in the future as a target place, and can accept a visiting date and time as a target date and time. According to such an information processing device 10, the user can grasp a situation on a visiting date and time of a visiting place to visit in the future by confirming the simulation virtual space. According to such an information processing device 10, the user can create an action plan for a future visit more efficiently and with a higher degree of satisfaction.

Furthermore, the information processing device 10 can accept the current position and the current date and time of the user as the target place and the target date and time. According to such an information processing device 10, the user can grasp the current situation of the facilities existing around the current position by confirming the simulation virtual space. According to such an information processing device 10, the user can efficiently determine what to do at the current position with higher degree of satisfaction.

### Third Example Embodiment

An information processing device 10 of a third example embodiment can determine candidates for an action to be performed at a target place on a target date and time in consideration of at least one of user-related information, word-of-mouth information by an unspecified large number of people, and a history of actions performed at the target place by the unspecified large number of people. Details will be described below.

The determination unit 13 can determine candidates for an action to be performed at the target place on the target date and time based on at least one of the following information:
User-related information related to user
Word-of-mouth information by unspecified large number of people
History of actions performed at target place by unspecified large number of people

For example, the determination unit 13 can determine candidates for an action to be performed at the target place on the target date and time based on at least one of the above information in addition to the information described in the second example embodiment. In one example, the determination unit 13 can narrow down the facilities to visit at the target place on the target date and time by the method described in the second example embodiment, and can further narrow down the facilities to visit at the target place on the target date and time based on at least one of the above information.

### User-Related Information Related to User

The user-related information indicates various contents related to each user. The user-related information of each user is registered in advance in the information processing device 10. Each user may register his/her user-related information in the information processing device 10. In addition, the information processing device 10 may estimate the user-related information of each user using a widely known technique such as image analysis and register the estimation result. The determination unit 13 grasps the user-related information of each user based on the registered information.

The user-related information may include, for example, at least one of the following: The user-related information is not limited to the example here.
Gender of the user
Age of the user
Nationality of the user
Hobby of the user
Preference of the user
Health state of the user
Budget of the user
Life goal of the user
Purpose of visiting the target place
Companion Information

In this example, information indicating a target user image of each facility may be registered in association with each of a plurality of facilities existing in the real world. In the information, a target user image of each facility is defined by using the above-described user-related information.

In an example of using the user-related information, the determination unit 13 calculates the similarity between the user and the user image by using the user-related information. Then, the candidates of the facility to be visited by the user can be narrowed down to, for example, a facility in which the similarity is equal to or higher than the threshold value. There are various methods for calculating the similarity, and a widely known technique can be used. For example, the determination unit 13 may calculate the similarity based on the number of items whose contents match with each other. In this case, the determination unit 13 calculates a higher similarity as the number is larger.

The contents of the “hobby of the user” and the “preference of the user” may be determined by each user and registered in the information processing device 10. In addition, the information processing device 10 may estimate a hobby or a preference of each user based on a past action history of each user. The action history may be a history of an action in the real world or a history of an action in the virtual space. The action history can indicate facilities visited in the past, things purchased in the past, services, web pages visited in the past, and the like. The action history of each user can be acquired using a widely known technique. For example, an action history of each user can be generated by analyzing an image of a surveillance camera installed in a facility, monitoring a current position of each user, monitoring an operation on a user terminal of each user, acquiring a history on a shopping site, and the like. By using such information, the determination unit 13 can determine candidates for an action matching the hobby or the preference of the user.

The “health state of the user” may be indicated by a predefined classification such as, for example, “healthy”, “have chronic disease”, or “regular visits to hospital”. By using such information, the determination unit 13 can determine candidates for an action according to the health state of the user.

The “budget of the user” is a budget for an action at the target place on the target date and time. By using such information, the determination unit 13 can determine candidates for an action according to the budget of the user.

The “life goal of the user” may be indicated by a predefined classification, for example, “want to live healthily”, “want to enjoy anyway”, “want to enjoy without spending money”, “want to exercise moderately”, or the like. By using such information, the determination unit 13 can determine candidates for an action according to the life goal of the user.

The “purpose of visiting the target place” may be indicated in a predefined classification such as “date”, “family trip”, “solitary travel”, “graduation trip”, “change of mood”, “overseas travel”, “learning”, “exercise”, or the like. By using such information, the determination unit 13 can determine candidates for an action according to the purpose of visiting the target place. For example, the determination unit 13 can determine, as a candidate, a facility in which a user who is to travel overseas can learn culture, customs, and the like of the region. Furthermore, the determination unit 13 can determine a facility suitable for a date or the like as candidates for the user who is to go on a date or the like. Furthermore, it is possible to determine an educational facility such as a library or a museum as candidates for the user who learns.

The “companion information” is information on a person accompanying the visit to the target place. The companion information may include the number of companions. In addition, the companion information may include characteristics of the companion (girlfriend, boyfriend, family, friend, colleague, etc.). By using such information, the determination unit 13 can determine candidates for an action according to the situation of the companion of the user.

Furthermore, by using information such as the gender, the age, and the nationality of the user, the determination unit 13 can determine candidates for an action according to these attributes.

### Word-of-Mouth Information by Unspecified Large Number of People

The word-of-mouth information is information posted by an unspecified large number of people to each facility. The word-of-mouth information may include information obtained by evaluating each facility by the number of stars. For example, the word-of-mouth information may include the number of stars determined by each of an unspecified large number of people. Furthermore, the word-of-mouth information may include statistical values (examples: average value, maximum value, minimum value, median value, mode value, etc.) of the number of stars determined by each of an unspecified large number of people. The determination unit 13 can acquire word-of-mouth information of each facility from a server that accepts posting of word-of-mouth information for each facility.

In an example of using word-of-mouth information by an unspecified large number of people, the determination unit 13 can narrow down candidates of facilities to be visited by the user to, for example, facilities whose statistical value of the number of stars is equal to or greater than a threshold value.

As a modified example, the word-of-mouth information may be associated with attribute information of a contributor. The attribute information can include the same content as the user-related information. In the modified example, the determination unit 13 calculates a similarity between the attribute of the user and the attribute of each contributor, and specifies a contributor whose similarity is equal to or greater than a threshold value. Next, the determination unit 13 calculates a statistical value of the number of stars of each facility indicated by the word-of-mouth information of the identified contributor. Then, the determination unit 13 can narrow down the candidates of the facility to be visited by the user to facilities in which the statistical value of the number of stars calculated in this manner is equal to or greater than the threshold value. There are various methods for calculating the similarity between the attribute of the user and the attribute of each contributor, and a widely known technique can be used. For example, the determination unit 13 may calculate the similarity based on the number of items whose contents match with each other. In this case, the determination unit 13 calculates a higher similarity as the number is larger.

The word-of-mouth information may include the number of “likes” given by the user to each facility. Then, the determination unit 13 may use the “number of likes of each facility” instead of the“statistical value of the number of stars of each facility”.

As another example, the determination unit 13 may analyze word-of-mouth information described in a natural language using a natural language processing technology. For example, the determination unit 13 may input word-of-mouth information collected in generative artificial intelligence (AI), and may extract a popular facility or a facility with good reputation based on the input word-of-mouth information. Then, the determination unit 13 may narrow down the candidates of the facility to be visited by the user to the popular facility or the facility with good reputation specified in this manner. The determination unit 13 may cause the generative AI to estimate which facility each piece of word-of-mouth information refers to from the content of each piece of word-of-mouth information. The estimation may be achieved using position information (posted position) associated with each piece of word-of-mouth information.

In addition, the determination unit 13 may input word-of-mouth information collected to the generative AI and an attribute of a contributor, and may propose a recommended facility to a user having a predetermined attribute based on the input word-of-mouth information and attribute. Then, the determination unit 13 may narrow down the candidates of the facility to be visited by the user to the facility recommended by the generative AI.

The generative AI is a concept including a large language model (LLM). In addition, the generative AI can include an image analysis model. The generative AI interprets content of a prompt input in a natural language, generates an answer to the input prompt based on data learned in advance, and outputs the answer expressed in the natural language. In addition, the generative AI can accept an input of an image or the like together with a prompt, interpret content of the input image or the like, and generate an answer reflecting a result of the interpretation. Furthermore, the generative AI can also generate and output an image. Such generative AI is achieved by, for example, a neural network. The neural network includes a plurality of artificial neurons and has synapses connecting the neurons. Each synapse has a weight. Upon accepting an input, such a neural network performs calculation using a weight associated with each synapse, and performs output corresponding to the input. The model representing the connection relationship between the neuron and the synapse is saved in the memory in, for example, the form of software. Alternatively, the model may be achieved as a dedicated circuit. Similarly, the weight of each synapse is also saved in the memory in the form of software. In addition, a circuit representing a weight may be mounted in a dedicated circuit. In a case where the generative AI is configured using a plurality of models, not all models necessarily need to be saved in the same memory. There are various models that use such a neural network. The generative AI may be achieved by adopting and replacing various models such as a Transformer, a Convolutional Neural Network (CNN), and a Recurrent Neural Network (RNN).

The information processing device 10 may perform processing of giving a reward to the contributor to the used word-of-mouth information. The way of giving a reward can be achieved using a widely known technique.

As another modified example, the word-of-mouth information may be anonymized. That is, the word-of-mouth information may be input to the information processing device 10 in a state of not being associated with the identification information of the contributor. The privacy protection of the contributor is thereby achieved.

### History of Actions Performed at a Target Place by Unspecified Large Number of People

The history of actions performed by an unspecified large number of people at the target place indicates, for example, a history of actions performed in the past by an unspecified large number of people at the target place. For example, the determination unit 13 can acquire, from a server that analyzes a facility visited by each person, information indicating a facility visited by each of an unspecified large number of people at a target place. The server may specify a facility visited by each person by analyzing a surveillance camera image photographed at each place. In addition, the server may specify the facility visited by each person by comparing the current position of each person with the position of each facility. The server can specify the current position of each person based on the current position information of the terminal possessed by each person.

In an example in which a history of actions performed by an unspecified large number of people at a target place is used, the determination unit 13 analyzes actions of a large number of people using, for example, a machine learning algorithm, and can narrow down candidates for facilities to be visited by the user to facilities having a predetermined analysis result. The facility having a predetermined analysis result is, for example, a popular facility.

For example, the determination unit 13 may determine the popularity ranking of facilities in descending order of the number of visitors in a predetermined period. The determination unit 13 may then determine a facility whose rank in the popularity ranking satisfies a predetermined condition as a popular facility. Examples of the condition include, but are not limited to, “a rank in a popularity ranking is equal to or higher than a predetermined rank”, “a rank in a popularity ranking is within the top X %”, and the like.

As a modified example, the history of the actions may further indicate attribute information of each person. The attribute information can include the same content as the user-related information. In the modified example, the determination unit 13 calculates a similarity between the attribute of the user and the attribute of each person, and specifies a person whose similarity is equal to or greater than a threshold value. Next, the determination unit 13 can determine the popularity ranking of facilities in descending order of visits by a specified person in a predetermined period. The determination unit 13 may then determine a facility whose rank in the popularity ranking satisfies a predetermined condition as a popular facility. Examples of the condition include, but are not limited to, “a rank in a popularity ranking is equal to or higher than a predetermined rank”, “a rank in a popularity ranking is within the top X %”, and the like. There are various methods for calculating the similarity between the attribute of the user and the attribute of each person, and a widely known technique can be used. For example, the determination unit 13 may calculate the similarity based on the number of items whose contents match with each other. In this case, the determination unit 13 calculates a higher similarity as the number is larger.

As another modified example, the history of actions may further indicate environmental information at a timing each person visits each facility. The environmental information includes, but is not limited to, a time zone, a climate, a month, a day of the week, and the like. In the modified example, the determination unit 13 calculates a similarity between the environment of the target date and time and the environment of each timing indicated by the action history, and specifies a timing at which the similarity is equal to or greater than a threshold value. Next, the determination unit 13 may determine the popularity ranking of facilities in descending order of the number of visitors at the specified timing. The determination unit 13 may then determine a facility whose rank in the popularity ranking satisfies a predetermined condition as a popular facility. Examples of the condition include, but are not limited to, “a rank in a popularity ranking is equal to or higher than a predetermined rank”, “a rank in a popularity ranking is within the top X %”, and the like. There are various methods of calculating the similarity between the environment of the target date and time and the environment of each timing indicated by the action history, and a widely known technique can be used. For example, the determination unit 13 may calculate the similarity based on the number of items whose contents match with each other. In this case, the determination unit 13 calculates a higher similarity as the number is larger.

Data indicating a history of actions performed by an unspecified large number of people at a target place may be anonymized. That is, the data indicating the history of the action of each person may be input to the information processing device 10 in a state of not being associated with the identification information of each person. The privacy protection of each person is thereby achieved.

Other configurations of the information processing device 10 can be similar to those of the first and second example embodiments.

According to the information processing device 10 of the third example embodiment, operations and effects similar to those of the information processing devices 10 of the first and second example embodiments can be achieved. Furthermore, the information processing device 10 can determine candidates for an action to be performed at a target place on a target date and time in consideration of at least one of user-related information, word-of-mouth information by an unspecified large number of people, and a history of actions performed at the target place by the unspecified large number of people. According to such an information processing device 10, candidates for an action more suitable for the user can be determined and provided to the user. In addition, candidates for an action can be determined by reflecting a fashion or a trend, and provided to the user. As a result, the user can more efficiently create an action plan with a higher degree of satisfaction.

### Fourth Example Embodiment

An information processing device 10 of a fourth example embodiment accepts an input for changing the target date and time and the target place, and updates the content of the displayed simulation virtual space and the content of the candidates for an action to be performed at the target place on the target date and time according to the input. Details will be described below.

The acceptance unit 11 accepts change of a target date and time and a target place.

For example, the acceptance unit 11 may accept an input to change the target date and time by an input for shifting the target date and time forward or backward from the currently designated date and time. Furthermore, the acceptance unit 11 may accept an input to change the target place by an input for shifting the target place from the currently designated place in an arbitrary direction.

In one example, as illustrated in FIG. 5, the generation unit 12 positions the character C operated by the user at the target place in the simulation virtual space. The acceptance unit 11 accepts an input for moving the character C in the simulation virtual space from the user. Then, the acceptance unit 11 can accept the position of the character C after the movement as the target place after the change (new target place). The acceptance of an input for moving the character C in the simulation virtual space and the movement of the character C based on the input can be achieved using a widely known technique.

In the case of this example, the acceptance unit 11 may calculate the movement time required to move from the target place before the change to the target place after the change. Then, the generation unit 12 may determine, as the target date and time after the change, a date and time after the “calculated movement time” has elapsed from the “target date and time corresponding to the target place before the change”. That is, in the case of this example, the generation unit 12 may not accept the designation of the target date and time after the change from the user, and may automatically change the target date and time in conjunction with the movement of the target place. The calculation of the time required for movement between two points can be achieved using a widely known technique. For example, the generation unit 12 can calculate the time required for the movement between two points by dividing the movement distance (distance along the road) between the two points by a predefined general walking speed.

The generation unit 12 achieves the situation of the target place after the change in the target date and time after the change in the simulation virtual space. Then, the output unit 14 updates the display content of the screen provided to the user. Specifically, the output unit 14 updates from the simulation virtual space indicating the situation of the target place before the change on the target date and time before the change to the simulation virtual space indicating the situation of the target place after the change on the target date and time after the change.

Furthermore, the determination unit 13 determines candidates for an action to be performed at the target place after the change on the target date and time after the change based on the situation of the target place after the change on the target date and time after the change. Then, the output unit 14 updates the display content of the screen provided to the user. Specifically, the output unit 14 updates from the candidates for the action to be performed at the target place before the change on the target date and time before the change to the candidates for the action to be performed at the target place after the change on the target date and time after the change.

Other configurations of the information processing device 10 can be similar to those of the first to third example embodiments.

According to the information processing device 10 of the fourth example embodiment, operations and effects similar to those of the information processing devices 10 of the first to third example embodiments can be achieved. Furthermore, an information processing device 10 accepts an input to change the target date and time and the target place, and updates the content of the displayed simulation virtual space and the content of the candidates for an action to be performed at the target place on the target date and time according to the input.

According to such an information processing device 10, the user can determine an action to be performed at each place while simulating movement at the target place on the target date and time. As a result, the user can more efficiently create an action plan with a higher degree of satisfaction.

### EXAMPLES

Here, an example of the information processing device 10 will be described by using a specific example. The example described here is merely an example, and is not limited to this example. Here, it is assumed that the user creates a future date plan.

Since the user will meet at station A at 10:00 on Feb. 9, 2025, the user first designates the target date and time “10:00 on Feb. 9, 2025 ” and the target place “station A”, and inputs the same to the information processing device 10.

The information processing device 10 generates a simulation virtual space in which the situation near station A at 10:00 on Feb. 9, 2025 is achieved, and displays the simulation virtual space on the screen. Furthermore, the information processing device 10 determines candidates for an action to be performed near station A at 10:00 on Feb. 9, 2025, and displays the candidates for the actions on the screen. For example, the information processing device 10 can generate a screen as illustrated in FIG. 5 and display the screen on the user terminal.

At this time, as described in the second example embodiment, the information processing device 10 can determine candidates for an action in consideration of the weather condition near station A and the situation of the facility near station A at 10:00 on Feb. 9, 2025. Furthermore, as described in the third example embodiment, the information processing device 10 can determine candidates for an action in consideration of user-related information (visiting purpose, budget, etc.), word-of-mouth information by an unspecified large number of people, a history of actions performed by an unspecified large number of people near station A, and the like.

The user can make an input to adopt one of the proposed candidates. Upon accepting the input, the information processing device 10 registers the adopted action in association with the target date and time (the date and time displayed at the lower right of FIG. 5) at that time. Furthermore, the information processing device 10 may identify and display a facility adopted as a facility to be visited in the simulation virtual space. There are various methods for identifying and displaying. For example, the information processing device 10 may achieve the identification and display by changing a display target (brightness, color, size, etc.) of a facility to be visited.

The user may access a home page or a menu page of each facility from a link displayed on the screen before making an input to adopt one of the proposed candidates. Furthermore, the user may reproduce an advertisement, a moving image, or the like displayed on the screen.

In addition, the user may make an input to move the position of the character C without making an input to adopt one of the proposed candidates. The information processing device 10 changes the position of the character C in the simulation virtual space in accordance with the input. Then, the information processing device 10 accepts the position after the change as the target place. Furthermore, the information processing device 10 calculates the time required for the movement, and advances the target date and time by the calculated time.

Then, the information processing device 10 generates a simulation virtual space in which the situation of the target place after the change on the target date and time after the change is achieved, and displays the simulation virtual space on the screen. As a result, the position of the character C and the peripheral situation on the screen of FIG. 5 are updated. Furthermore, the information processing device 10 determines candidates for an action to be performed at the target place after the change on the target date and time after the change based on the situation of the target place after the change on the target date and time after the change, and displays the candidates on the screen. In addition, the information processing device 10 updates the target date and time at the lower right on the screen of FIG. 5 to a new target date and time.

The user can make an input to adopt one of the newly proposed candidates. Upon accepting the input, the information processing device 10 registers the adopted action in association with the target date and time (the date and time displayed at the lower right of FIG. 5) at that time.

The user may be able to make an input to turn back time. In response to the input, the information processing device 10 can perform a display of returning the movement of the character C so far in the reverse direction. Then, the user may change the previously adopted action after returning time. For example, the user can change (optimize) an action to be performed at a previous time based on an action determined to be performed at a later time. The user can brush up the action plan while changing time forward or backward.

In addition, the user may be able to make an input to advance time without changing the position of the character C. For example, the user advances the time by the staying time in a certain facility. If the user makes an input to adopt one of the proposed candidates, the information processing device 10 may ask the user for the scheduled staying time accordingly. Then, the information processing device 10 may advance the time by the scheduled staying time input by the user.

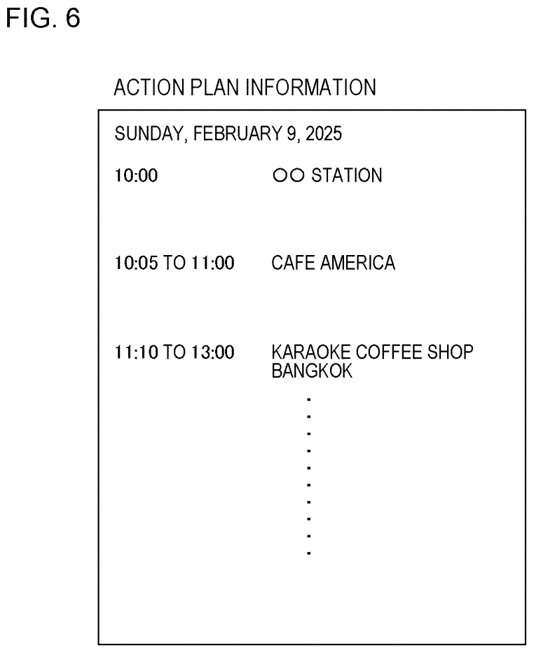

The user can create a date plan by repeating the above processing. The information processing device 10 can generate and output/save action plan information summarizing the action adopted by the user. For example, as illustrated in FIG. 6, the information processing device 10 can generate action plan information in which actions adopted by the user are displayed in chronological order in association with execution date and time (target date and time at the time of adoption).

### Modified Examples

Hereinafter, modified examples applicable to the first to fourth example embodiments will be described. In these modified examples as well, the operations and effects similar to those of the first to the fourth example embodiments are achieved.

### First Modified Example

The information processing device 10 may have a multi-language function. That is, the information processing device 10 may be able to display information to be displayed on the screen in multiple languages. The information processing device 10 can display various types of information in the language selected by the user.

### Second Modified Example

The determination unit 13 can determine candidates for an action to be performed at the target place on the target date and time by a characteristic method in consideration of the user's health condition, the user's life goal, the purpose of visiting the target place, and the like.

For example, in a case where the health condition of the user is a content that requires predefined consideration, such as “have chronic disease” or “regular visits to hospital”, the determination unit 13 can execute first processing defined in advance.

In the first processing, the determination unit 13 may determine, as candidates for an action, a “facility where one can take a break” at an arbitrary timing (e.g., every predetermined time) during the simulation described in the above example. The facility where the user can take a break is a cafe, a restaurant, or the like, and is defined in advance.

In addition, in a case where it is indicated to exercise in the life goal of the user (“want to exercise moderately” etc.), the determination unit 13 can execute second processing defined in advance. In addition, in a case where the visiting purpose of the target place is to exercise, the determination unit 13 can execute the second processing defined in advance.

In the second processing, the determination unit 13 may determine, as candidates for an action, a “facility where one can exercise” at an arbitrary timing (e.g., every predetermined time) during the simulation described in the above example. The facility where the user can exercise is bowling alley, park, or the like, and is defined in advance.

### Third Modified Example

The determination unit 13 may estimate the congestion situation of the road at the target place on the target date and time. Then, the determination unit 13 may propose a non-crowded movement route to the user during the simulation described in the above example. For example, the determination unit 13 may notify the user of the congested road by further displaying information indicating the congested road on the screen displaying the simulation virtual space.

The determination unit 13 can estimate the congestion situation of the road based on a month, a day of the week, a time zone, weather information, an event situation held in the vicinity, and the like. For example, the determination unit 13 may estimate the congestion situation of the road at the target place on the target date and time by using an estimation level obtained by learning the correlation between the past congestion situation of the road and these item values.

### Fourth Modified Example

As described in detail in the second example embodiment, the determination unit 13 can determine candidates for an action to be performed at the target place on the future target date and time based on the prediction content of the weather information of the target place on the future target date and time. However, the weather information of the target place on the future target date and time is merely a prediction content, and it is not clear whether the weather information will be so.

Therefore, determination unit 13 may determine a plurality of candidates for an action for each weather as candidates for an action to be performed at the target place on the target date and time. For example, the determination unit 13 may determine candidates for an action under a plurality of conditions such as candidates for an action in the case of sunny weather and candidates for an action in the case of rainy weather. Then, the output unit 14 may output a plurality of candidates for an action corresponding to the weather.

### Fifth Modified Example

The processing of the fifth modified example is executed in a scene where the user is actually performing an action according to the action plan created in advance. The information processing device 10 can propose a more efficient movement plan in consideration of real-time traffic information.

The information processing device 10 can include traffic information acquisition means. The traffic information acquisition means can acquire a real-time traffic status, operation information, a congestion situation, and the like in cooperation with an application programing interface (API) of public transportation and a road traffic information system.

Furthermore, the information processing device 10 can include a route optimization means. The route optimization means can calculate an optimum movement route and transportation means in consideration of the acquired traffic information, an action plan created in advance by the user, a distance between destinations, a time constraint, and the like.

Furthermore, the information processing device 10 can include a dynamic update means. In a case where the traffic status changes during the user's action, the dynamic update means can update the action plan in real time and propose alternative routes and transportation means. For example, in a case where a moving means is defined such as movement by car or movement by bus in the action plan, the information processing device 10 can update the moving means according to the current situation.

Furthermore, the information processing device 10 can include an energy efficiency calculation means. The energy efficiency calculation means calculates the environmental load of the proposed action plan and presents more environmentally friendly options.

According to the information processing device 10 having these elements, not limited to simple display and recommendation of information, specific and technical improvement by cooperation with a complicated traffic system can be provided. As a result, the movement efficiency of the user is improved, which also contributes to social benefits such as mitigation of traffic congestion and reduction of environmental load. This modified example provides a specific technical solution to a specific technical problem (efficient movement planning and execution).

### Sixth Modified Example

The information processing device 10 may display a moving image such as an advertisement in the simulation virtual space. In a case where the moving image includes a voice, the user may be able to select whether to output the voice at the time of reproducing the moving image. The information processing device 10 can output voice or not output voice according to the selection of the user.

The information processing device 10 may output a default sound to the simulation virtual space. The default sound may be a sound indicating the situation of the target place on the target date and time. Examples of such sound include, but are not limited to, wind sound, rain sound, and the like. In a case where the voice of the moving image is output during the reproduction of the moving image, the user may be able to select whether to stop the default sound in the simulation virtual space or continue to output the sound. The information processing device 10 can output or not output the default sound of the simulation virtual space according to the selection of the user.

### Seventh Modified Example

As illustrated in FIG. 5, the information processing device 10 can indicate a route from the target place to each facility with an arrow or the like. Then, upon accepting a user input for selecting an arrow, the information processing device 10 may move the character C in the direction of the arrow accordingly. In addition, upon accepting a user input for selecting an arrow, the information processing device 10 may instantaneously move the character C to a facility corresponding to the arrow. Alternatively, upon accepting a user input for selecting an arrow, the information processing device 10 may quickly move the character C to a facility corresponding to the arrow by fast-forwarding. The information processing device 10 may accept selection from the user by which method to move the character C.

### Eighth Modified Example

An advertisement or other information displayed in the simulation virtual space may be saved in advance in the information processing device 10 in association with date and time. For example, information indicating a certain time zone by date, such as “Jan. 1, 2025 to Feb. 28, 2025” may be associated with an advertisement or the like. In addition, information indicating a certain time zone by time such as “13:00 to 17:00” may be associated with an advertisement or the like. In addition, information indicating a certain time zone by day of the week such as “Monday to Friday” may be associated with an advertisement or the like. Furthermore, classifications such as season, morning time, lunch time, snack time, and dinner time may be associated with an advertisement or the like. In the case of this example, a detailed time zone of each classification is defined in advance by a date, a time, a day of the week, and the like.

Then, the information processing device 10 can display information such as an advertisement associated with a time zone including the target date and time in the simulation virtual space.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each example embodiment can be appropriately combined with other example embodiments.

In the flowchart used in the descriptions above, a plurality of steps (processing) is described in order. However, an execution order of the steps executed in each example embodiment is not limited to the described order. In each example embodiment, the order of the illustrated steps can be changed within a range in which there is no problem in content.

Some or all of the above example embodiments may be described as the following Supplementary Notes, but are not limited to the following.
1. An information processing device including,
an acceptance means for accepting designation of a target date and time and a target place,
a generation means for generating a virtual space in which a real world is reproduced, the virtual space being a simulation virtual space in which a situation of the target place on the target date and time is achieved,
a determination means for determining, based on a situation of the target place on the target date and time, candidates for an action to be performed at the target place on the target date and time. and
an output means for outputting the simulation virtual space and information indicating the candidates for an action.
2. The information processing device according to 1, in which
the determination means determines the candidates for an action to be performed at the target place on the target date and time with reference to date and time related information related to date and time, the information being information regarding each of a plurality of facilities existing in the real world.
3. The information processing device according to 2, in which
the date and time related information includes at least one of,
business hours,
a crowding situation of the target place, and
date and time of an event held in a facility.
4. The information processing device according to any one of 1 to 3, in which
the determination means determines the candidates for an action to be performed at the target place on the target date and time based on content of weather information of the target place on the target date and time.
5. The information processing device according to any one of 1 to 4, in which
the determination means determines the candidates for an action to be performed at the target place on the target date and time based on at least one of,
user-related information related to a user,
word-of-mouth information by an unspecified large number of people, and
a history of actions performed by the unspecified large number of people at the target place.
6. The information processing device according to 5, in which
the user-related information includes at least one of,
a health condition of the user,
a budget of the user, and
a visiting purpose of the target place.
7. The information processing device according to any one of 1 to 6, in which
the acceptance means accepts a change of the target date and time and the target place,
the generation means achieves a situation of the target place after the change on the target date and time after the change in the simulation virtual space, and
the determination means determines candidates for an action to be performed at the target place after the change on the target date and time after the change based on the situation of the target place after the change on the target date and time after the change.
8. The information processing device according to 7, in which
the generation means positions a character operated by a user at the target place of the simulation virtual space, and
the acceptance means,
accepts an input for moving the character in the virtual space, accepts a position of the character after the movement as the target place after the change,
calculates a movement time required for movement from the target place before the change to the target place after the change, and
determines, as the target date and time after the change, date and time after elapse of the movement time from the target date and time corresponding to the target place before the change.
9. An information processing method, in which one or more computers,
accept designation of a target date and time and a target place,
generate a virtual space in which a real world is reproduced, the virtual space being a simulation virtual space in which a situation of the target place on the target date and time is achieved,
determine, based on a situation of the target place on the target date and time, candidates for an action to be performed at the target place on the target date and time, and
output the simulation virtual space and information indicating the candidates for an action.
10. A program for causing a computer to execute processing including,
accepting designation of a target date and time and a target place,
generating a virtual space in which a real world is reproduced, the virtual space being a simulation virtual space in which a situation of the target place on the target date and time is achieved,
determining, based on a situation of the target place on the target date and time, candidates for an action to be performed at the target place on the target date and time, and
outputting the simulation virtual space and information indicating the candidates for an action.

Some or all of supplementary notes 2 to 8 dependent on the information processing device of supplementary note 1 described above can also be dependent on the information processing method of supplementary note 9 and the program of supplementary note 10 by the same dependency relationship as in supplementary note 1 and supplementary notes 2 to 8. Furthermore, a part or all of the configuration described as a supplementary note can be achieved in various pieces of hardware, software, various recording means for recording software, or systems without departing from the above-described example embodiments.

1. An information processing apparatus comprising:
at least one memory configured to store one or more instructions; and
at least one processor configured to execute the one or more instructions to:
accept designation of a target date and time and a target place;
generate a virtual space in which a real world is reproduced, the virtual space being a simulation virtual space in which a situation of the target place on the target date and time is achieved;
determine, based on a situation of the target place on the target date and time, candidates for an action to be performed at the target place on the target date and time; and
output the simulation virtual space and information indicating the candidates for an action.

2. The information processing apparatus according to claim 1, wherein
the at least one processor is further configured to execute the one or more instructions to determine the candidates for an action to be performed at the target place on the target date and time with reference to date and time related information related to date and time, the information being information regarding each of a plurality of facilities existing in the real world.

3. The information processing apparatus according to claim 2, wherein
the date and time related information includes at least one of,
business hours,
a crowding situation of the target place, and
date and time of an event held in a facility.

4. The information processing apparatus according to claim 1, wherein
the at least one processor is further configured to execute the one or more instructions to determine the candidates for an action to be performed at the target place on the target date and time based on content of weather information of the target place on the target date and time.

5. The information processing apparatus according to claim 1, wherein
the at least one processor is further configured to execute the one or more instructions to determine the candidates for an action to be performed at the target place on the target date and time based on at least one of,
user-related information related to a user,
word-of-mouth information by an unspecified large number of people, and
a history of actions performed by the unspecified large number of people at the target place.

6. The information processing apparatus according to claim 5, wherein
the user-related information includes at least one of,
a health condition of the user,
a budget of the user, and
a visiting purpose of the target place.

7. The information processing apparatus according to claim 1, wherein the at least one processor is further configured to execute the one or more instructions to
accept a change of the target date and time and the target place,
achieve a situation of the target place after the change on the target date and time after the change in the simulation virtual space, and
determine candidates for an action to be performed at the target place after the change on the target date and time after the change based on the situation of the target place after the change on the target date and time after the change.

8. The information processing apparatus according to claim 7, wherein the at least one processor is further configured to execute the one or more instructions to
position a character operated by a user at the target place of the simulation virtual space,
accept an input for moving the character in the virtual space,
accept a position of the character after the movement as the target place after the change,
calculate a movement time required for movement from the target place before the change to the target place after the change, and
determine, as the target date and time after the change, date and time after elapse of the movement time from the target date and time corresponding to the target place before the change.

9. An information processing method, in which one or more computers,
accept designation of a target date and time and a target place,
generate a virtual space in which a real world is reproduced, the virtual space being a simulation virtual space in which a situation of the target place on the target date and time is achieved,
determine, based on a situation of the target place on the target date and time, candidates for an action to be performed at the target place on the target date and time, and
output the simulation virtual space and information indicating the candidates for an action.

10. The information processing method according to claim 9, wherein
the one or more computers determine the candidates for an action to be performed at the target place on the target date and time with reference to date and time related information related to date and time, the information being information regarding each of a plurality of facilities existing in the real world.

11. The information processing method according to claim 10, wherein
the date and time related information includes at least one of,
business hours,
a crowding situation of the target place, and
date and time of an event held in a facility.

12. The information processing method according to claim 9, wherein
the one or more computers determine the candidates for an action to be performed at the target place on the target date and time based on content of weather information of the target place on the target date and time.

13. The information processing method according to claim 9, wherein
the one or more computers determine the candidates for an action to be performed at the target place on the target date and time based on at least one of,
user-related information related to a user,
word-of-mouth information by an unspecified large number of people, and
a history of actions performed by the unspecified large number of people at the target place.

14. The information processing method according to claim 13, wherein
the user-related information includes at least one of,
a health condition of the user,
a budget of the user, and
a visiting purpose of the target place.

15. A non-transitory computer-readable medium storing a program for causing a computer to:
accept designation of a target date and time and a target place;
generate a virtual space in which a real world is reproduced, the virtual space being a simulation virtual space in which a situation of the target place on the target date and time is achieved;
determine, based on a situation of the target place on the target date and time, candidates for an action to be performed at the target place on the target date and time; and
output the simulation virtual space and information indicating the candidates for an action.

16. The non-transitory computer-readable medium according to claim 15, wherein
the program causes the computer to determine the candidates for an action to be performed at the target place on the target date and time with reference to date and time related information related to date and time, the information being information regarding each of a plurality of facilities existing in the real world.

17. The non-transitory computer-readable medium according to claim 16, wherein
the date and time related information includes at least one of,
business hours,
a crowding situation of the target place, and
date and time of an event held in a facility.

18. The non-transitory computer-readable medium according to claim 15, wherein
the program causes the computer to determine the candidates for an action to be performed at the target place on the target date and time based on content of weather information of the target place on the target date and time.

19. The non-transitory computer-readable medium according to claim 15, wherein
the program causes the computer to determine the candidates for an action to be performed at the target place on the target date and time based on at least one of,
user-related information related to a user,
word-of-mouth information by an unspecified large number of people, and
a history of actions performed by the unspecified large number of people at the target place.

20. The non-transitory computer-readable medium according to claim 19, wherein
the user-related information includes at least one of,
a health condition of the user,
a budget of the user, and
a visiting purpose of the target place.
